(19) United States
(12) Patent Application Publication
(10) Pub. No.: US 2010/0259162 A1
(43) Pub. Date: Oct. 14, 2010

(54) FILM FORMING DEVICE CONTROL METHOD, FILM FORMING METHOD, FILM FORMING DEVICE, ORGANIC EL ELECTRONIC DEVICE, AND RECORDING MEDIUM STORING ITS CONTROL PROGRAM

(75) Inventor: Kazuki Moyama, Amagasaki-shi (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/745,082

(22) PCT Filed: Nov. 28, 2008
(86) PCT No.: PCT/JP2008/071636

§ 371 Date: May 27, 2010

(30) Foreign Application Priority Data
Nov. 30, 2007 (JP) 2007-310252

(51) Int. Cl. H01J 1/62; B05D 5/06; C23C 16/52; C23C 16/00

(52) U.S. Cl. 313/504; 427/66; 118/697; 118/715

(57) ABSTRACT

A material having a low work function is quickly inserted near an interface between an organic layer and a cathode. A PM1 comprises a processing vessel (100), an evaporation device (200) for heating and evaporating the organic material, a first gas supply passage (150) communicating with the first evaporation source and transporting the organic material evaporated in the first evaporation source by using an inert gas; a dispenser (Ds) provided outside the processing vessel and heating and evaporating a second metal having a lower work function than that of a first metal forming a cathode, a second gas supply passage (320) communicating with the second evaporation source and transporting the second metal evaporated in the second evaporation source by using an inert gas, a discharge mechanism (120f) communicating with the gas supply passage (150, 320) and mixing the evaporated second metal into the evaporated organic material and discharging the mixture toward the object to be processed in the processing vessel, and controller (50) for controlling the proportion of the evaporated second metal to be mixed into the evaporated organic material.

### TECHNICAL FIELD

The present invention relates to a method of controlling a film-forming device which forms a film by mixing a material having a low work function into an organic material, a film-forming device of a cathode, an organic EL electronic device, and a recording medium having recorded thereon a program having processing procedure for executing on a computer the method of controlling a film-forming device.

### BACKGROUND ART

Recently, an organic EL (electroluminescence) display that uses an organic EL element emitting light using an organic compound has attracted attentions. Since organic EL elements self-illuminate, provide a fast response, and consume low power, and do not require a backlight, they are anticipated to be applied to, for example, display units of portable apparatuses.

The organic EL element is formed on a glass substrate and has a structure in which an organic layer is sandwiched between an anode layer (anode) and a cathode layer (cathode). When an electric current flows in the organic EL element by applying several external voltages, an electron is injected into the organic layer from the cathode side and a hole is injected into the organic layer from the anode side. When the electron and the hole are injected into the organic layer, an organic molecule is excited. When the excited organic molecule turns back to a ground state as the electron and the hole are recombined, surplus energy is emitted as light.

An organic EL element having high performance may be manufactured when the electron can be efficiently injected from the cathode side into the organic layer by lowering an electron injection barrier while injecting the electron into the organic layer. Accordingly, an electron injection layer formed of a material having a low work function, such as an alkali metal, is generally formed on an interface between the organic layer and the cathode (for example, refer to Non-Patent Document 1).

Non-Patent Document 1 discloses forming of an organic layer doped with a metal between each cathode and an emitter layer. A dopant metal may be, for example, lithium (Li), strontium (Sr), or samarium (Sm).

Since the alkali metal has a low work function, the alkali metal is preferable as a material for forming an electron injection layer. Meanwhile, since the alkali metal is a highly active species, even if the alkali metal is in the processing chamber in a high vacuum state, the alkali metal easily reacts with moisture, nitrogen, oxygen, or the like remaining in the processing chamber. Accordingly, a cathode is formed as soon as possible after the electron injection layer is formed, and thus the electron injection layer may be covered by the cathode.

Accordingly, in order to stably form the electron injection layer, a vacuum evaporation method (co-evaporation method) is suggested, wherein an alkali metal, such as lithium or the like, and an organic material, such as Alq3 or the like, are contained in separate containers in the same processing chamber, and are separately evaporated, thereby having each vapor being mixed with each other during diffusion, and deposited on a object.

(Non-Patent Document 1) “Bright organic electroluminescent devices having a metal-doped electron-injecting layer” 1998 American Institute of Physics, Applied PhysicsLetters, VOLUME 73, NUMBER 20, 16 NOV. 1998

### DISCLOSURE OF THE INVENTION

### Technical Problem

However such a method has inferior controllability, and it is difficult to precisely control a proportion of an alkali metal mixed into an organic layer in consideration of electron injection efficiency, and to precisely control the alkali metal to be uniformly mixed in the organic layer. Specifically, there is a movement of providing an organic EL device on a large substrate recently, and thus it is very difficult form a more uniform film on a large substrate by using a general co-evaporation method.

In order to form a cathode as soon as possible after an electron injection layer is formed, vacuum evaporation for forming an alkali metal layer, or the like and sputtering for forming a cathode may be consecutively performed in the same chamber. However, the vacuum evaporation for forming an alkali metal layer, or the like and the sputtering for forming a cathode use different operation pressures. In other words, while forming the alkali metal layer, or the like, the chamber needs to be maintained in a desired vacuum state (depressurized state). On the other hand, while forming the cathode, a sputtering gas needs to be supplied to the chamber before forming the iii cathode, and at this time, the pressure of the chamber inevitably increases to some degree. Accordingly, the film such as alkali metal, and the cathode cannot be consecutively formed according to the operation principle.

Moreover, in order to consecutively perform the sputtering of a cathode after the vacuum evaporation in the same chamber, unnecessary alkali metal gas, or the like needs to be exhausted to the outside so that the alkali metal gas, or the like used during the vacuum evaporation does not flow toward a sputtering film-forming mechanism, and the sputtering needs to be performed by introducing a sputtering gas in a state that the gas such as alkali metal, and the sputtering gas are no longer mixed with each other. Thus, it is difficult to perform the sputtering of a cathode consecutively after the vacuum evaporation.

Therefore, to address this problem, the present invention provides a method of controlling a film-forming device for quickly inserting a material having a low work function near an interface between an organic layer and a cathode, the film-forming method, the film-forming device, an organic EL electronic device, and a recording medium recorded thereon a program for the control.

### Technical Solution

To solve the above-mentioned problems, according to an aspect of the present invention, there is provided a method of controlling a film-forming device which forms an organic layer on a object. The film-forming device includes a processing vessel, a first evaporation source which heats and evaporates the organic material, a first gas supply passage which communicates with the first evaporation source, and transports the organic material evaporated in the first evaporation source by using an inert gas, a second evaporation source which is formed outside the processing chamber, and heats and evaporates a second metal having a lower work function than that of a first metal forming a cathode, a second gas supply passage which communicates with the second evaporation source and transports the second metal evaporated in the second evaporation source by using an inert gas, and a discharge mechanism which communicates with the first gas supply passage and the second gas supply passage, mixes the evaporated second metal with the evaporated organic material and then discharge the mixture toward the object in the processing vessel, thereby the method controls a proportion of the evaporated second metal mixed into the evaporated organic material.

According to the method, an organic layer is formed while controlling a proportion of the second metal mixed into the organic layer. Accordingly, by mixing the second metal having the low work function into the organic layer while forming the organic layer, substantially, the organic layer and an electron injection layer may be simultaneously formed. As a result, an atom of the second metal that is active may be prevented from reacting with moisture, nitrogen, oxygen, or the like remaining in the processing vessel. Thus, a highly efficient organic EL electronic device having high electron injection efficiency may be stably manufactured.

Here, the proportion of the second metal mixed into the organic layer under formation is very important. This is well known from a research result that in a conventional organic EL electronic device manufactured by stacking an electron transport layer, an electron injection layer, and a cathode on a light emission layer, a thickness of an alkali metal forming the electron injection layer may be relatively smaller than a thickness of the cathode. For example, it has been reported that the thickness of the alkali metal, such as lithium, may be from about 0.5 to about 2.0 nm, and if the thickness is higher, electron injection efficiency is deteriorated.

Accordingly, considering importance of the proportion of the second metal mixed into the organic layer in the invention, a temperature of the first evaporation source may be controlled so as to control the proportion of the second metal mixed into the evaporated organic material.

Accordingly, an evaporation rate of the organic material contained in the first evaporation source may be controlled. In other words, when the temperature of a evaporation source is increased, the evaporation rate of the organic material is increased, thereby decreasing the proportion of the second metal mixed into the organic layer. On the other hand, when the temperature of the evaporation source is decreased, the evaporation rate of the organic material is decreased, thereby increasing the proportion of the second metal mixed into the organic layer.

The proportion of the second metal mixed into the evaporated organic material may be controlled by controlling a temperature of the second evaporation source.

Here as well, an evaporation rate of the second metal contained in the second evaporation source may be controlled. Here, when the temperature of a evaporation source is increased, the evaporation rate of the second metal is increased, thereby increasing the proportion of the second metal mixed into the organic layer. On the other hand, when the temperature of the evaporation source is decreased, the evaporation rate of the second metal is decreased, thereby decreasing the ratio of the second metal mixed in the organic layer. In order to control the temperature of each evaporation source, a voltage applied to a power supply of each evaporation source or an electric current supplied to the power supply may be controlled.

According to another method of controlling the proportion of the second metal mixed into the evaporated organic material, at least any one of flow rates of the inert gases supplied to the first gas supply passage and the second gas supply passage may be controlled.

The inert gases supplied to each gas supply passage are used as a carrier gas for transporting the organic material or the second metal. Accordingly, by increasing the flow rate of the inert gas, the amount of the second metal (evaporated molecules) transported per unit hour may be increased. As a result, the proportion of the second metal mixed into the organic layer may be increased. On the other hand, by decreasing the flow rate of the inert gas, the proportion of the second metal mixed into the organic layer may be reduced.

Similarly, by increasing the flow rate of the inert gas with respect to a vapor (evaporated molecules) of the organic material, the amount of organic material transported per unit hour may be increased. As a result, the proportion of the second metal mixed into the organic layer may be decreased. On the other hand, by decreasing the flow rate of the inert gas with respect to the vapor of the organic material, the proportion of the second metal mixed into the organic layer may be increased.

In the controlling of the temperature, some time is required for an evaporation source to actually reach a desired temperature after changing a voltage or an electric current, and thus a response is inferior. However, the controlling of the flow rate of the inert gas has better response than the controlling of the temperature. Accordingly, the amount of the second metal contained in the organic layer may be accurately controlled by roughly controlling the amount of the second metal by controlling the temperature, and then precisely controlling the amount of the second metal by controlling the flow rate of the inert gas.

The proportion of the second metal mixed into the evaporated organic material may be controlled by controlling a first opening/closing mechanism provided in the first gas supply passage. Alternatively, the proportion of the second metal mixed into the evaporated organic material may be controlled by controlling a second opening/closing mechanism provided in the second gas supply passage.

Here, the amount of the organic material passed through the first gas supply passage or the amount of the second metal passed through the second gas supply passage may be adjusted by adjusting an opening degree of the first opening/closing mechanism or an opening degree of the second opening/closing mechanism. Accordingly, the ratio of the second metal mixed in the evaporated organic material may be controlled.

The first opening/closing mechanism and the second opening/closing mechanism may be provided in the atmosphere. Accordingly, maintenance may be easily performed. Here, the atmosphere includes N₂, O₂, Ar, CO₂, Ne, He, CH₄, etc. as main components, and is in a state of 1 atm=1.013×10⁵ Pa. For example, according to an atmospheric pressure measuring method, a standard atmosphere is determined to be 1013.25 hPa for a surface pressure, 15° C. for a surface temperature, and 6.5° C./km for a lapse rate of temperature of 11 km or lower.

A thin film may be formed on the object up to a desired thickness by using the evaporated organic material without mixing the evaporated second metal, and then a predetermined amount of the evaporated second metal may be mixed into the evaporated organic material.

Here, the organic layer that is not mixed with the second metal is formed, and then the organic layer that is mixed with the second metal is immediately formed. Accordingly, for example, the second metal formed of an alkali metal or the like, which is a highly active species, may be prevented from being easily reacting with moisture, nitrogen, hydrogen, or the like, and at the same time, the thickness of the organic layer that is mixed with the second metal may be precisely adjusted.

The organic layer that is not mixed with the second metal and the organic layer that is mixed with the second metal are formed between the light emission layer and the cathode. Accordingly, the organic layer that is not mixed with the second metal and the organic layer that is mixed with the second metal are used as an electron transport layer adjacent to the light emission layer and an electron injection layer adjacent to the cathode. Thus, a highly efficient organic EL electronic device having high electron injection efficiency may be manufactured.

A amount of the second metal mixed into the evaporated organic material may be controlled to relatively increase.

Here, an organic film may be formed while gradually increasing the mixed amount of the second metal. Thus, the second metal may be mixed in the cathode in such a way that a proportion of the second metals to be mixed increases toward the cathode formed near the organic layer and decreases away from the cathode. In this manner, the highly efficient EL electronic device having the high electron injection efficiency may be manufactured.

Pipes for forming the first gas supply passage and the second gas supply passage may be controlled to be 200° C. or higher. Here, when the organic material is transported through the first gas supply passage by using the inert gas as a carrier gas, and the vapor of the second metal is transported through the second gas supply passage by using the inert gas as a carrier gas, each vapor may be prevented from being liquefied by being adhered to the pipes forming the first and second gas supply passages. Accordingly, the proportion of the second metal mixed into the organic material may be precisely controlled, while increasing an efficiency of use of material.

The second metal may be an alkali metal having a low work function. Examples of the alkali metal include lithium, sodium, potassium, rubidium, and cesium. Accordingly, electron injection efficiency may be increased. Also, the first metal may be a material mainly being silver or aluminum having low electrical resistivity and high reflectivity.

The film-forming device may include a loading stage which is movable while the object is placed thereon, a plurality of evaporation sources which includes the first evaporation source, a plurality of gas supply passages which includes the first gas supply passage communicating with each of the plurality of evaporation sources, and a plurality of discharge mechanisms. Here, different organic materials each evaporated from the each evaporation source are passed through each supply passage communicating with each evaporation source to be discharged from each mechanism, so as to consecutively film-form the different organic materials on the object placed on a loading stage moving to above each discharge mechanism, and the organic layer that is mixed with the evaporated second metal may be formed at the end of the consecutive film-formation.

Here, a plurality of films may be consecutively formed in the same processing vessel. Thus, a throughput is improved, thereby increasing productivity of a product. In addition, since it is not required to form many processing vessels for each formed film, a footprint is reduced, thereby reducing an installation charge.

The discharge mechanism may have a buffering space therein, and discharge the evaporated organic material and the evaporated second metal after passing the evaporated organic material and the evaporated second metal through the buffering space so that a pressure of the buffering space formed inside the discharge mechanism is higher than a pressure inside the processing vessel.

When the pressure of the buffering space inside the discharge mechanism is higher than the pressure inside the processing vessel, it is assumed that a phenomenon like a following is generated near a discharge opening. That is, at least some of gas molecules existing inside the discharge mechanism do not easily pass through the discharge opening, and repeat to reflect at an inner wall of the discharge mechanism and bounce back to the buffering space, and then go out from an opening of the discharge opening. In other words, gas molecules exceeding a predetermined amount from among gas molecules of the organic material and the second metal, which entered into the buffering space through the first and second gas supply paths after being evaporated in the first and second evaporation sources, are unable to immediately pass through the discharge opening but temporarily stay in the buffering space. Accordingly, the pressure in the buffering space is maintained to be a predetermined pressure (density) higher than the pressure inside the processing vessel. Thus, the gas molecules of the organic material and the second metal are mixed in the buffering space while staying in the buffering space, and thus are in somewhat uniform state.

As a result, these gas molecules are discharged from the discharge opening while maintaining a uniform state, thereby forming a uniform and high-quality film on the object.

To solve the above-mentioned problems, according to another aspect of the present invention, there is provided a film-forming method for forming an organic layer on an object, the film-forming method including heating and evaporating the organic material in a first evaporation source, transporting the evaporated organic material by using an inert gas, heating and evaporating a second metal having a lower work function than that of a first metal forming a cathode in a second evaporation source formed outside the processing vessel, transporting the evaporated second metal by using an inert gas and at that time, mixing the evaporated second metal into the evaporated organic material while controlling a proportion of the second metal mixed into the evaporated organic material, and discharging the evaporated organic material toward the object in the processing vessel.

To solve the above-mentioned problems, according to another aspect of the present invention, there is provided a film-forming device for forming an organic layer on an object, the film-forming device including a processing vessel, a first evaporation source which heats and evaporates the organic material, a first gas supply passage which communicates with the first evaporation source and transports the organic material evaporated in the first evaporation source by using an inert gas, a second evaporation source which is formed outside the processing chamber, heats and evaporates a second metal having a lower work function than that of a first metal forming a cathode, a second gas supply passage which communicates with the second evaporation source and transports the second metal evaporated in the second evaporation source by using an inert gas, a discharge mechanism which communicates with the first gas supply passage and the second gas supply passage, mixes the evaporated second metal with the evaporated organic material and then discharge the mixture toward the object in the processing vessel, and a controller which controls a proportion of the second metal mixed into the evaporated organic material.

To solve the above-mentioned problems, according to another aspect of the present invention, there is provided an organic EL electronic device manufactured by controlling a film-forming device according to the above method.

To solve the above-mentioned problems, according to another aspect of the present invention, there is provided a recording medium having recorded thereon a control program having processing procedure to be executed on a computer so as to control a film-forming device by using the above-mentioned method.

As such, the electron injection layer and the organic layer may be simultaneously formed by mixing the second metal having a low work function into the organic layer while the organic layer is formed. As such, an atom of the second metal may be prevented from reacting with moisture, nitrogen, oxygen, or the like remaining in the processing vessel. Accordingly, a highly efficient EL electronic device having high electron injection efficiency may be manufactured.

### ADVANTAGEOUS EFFECTS

As described above, according to the present invention, a material having a low work function can be quickly inserted near an interface between an organic layer and a cathode.

### BRIEF DESCRIPTION OF THE DRAWINGS

FIG. 1 is a diagram showing a process of manufacturing an organic EL electronic device, according to an embodiment of the present invention;

FIG. 2 is a diagram schematically showing a substrate-processing system according to the embodiment of the present invention;

FIG. 3 is a vertical cross-section view of a PM1 for performing a process of consecutively forming 6 layers, according to the embodiment of the present invention;

FIG. 4 is a diagram showing an organic EL element formed by a process of consecutively forming 6 layers, according to an embodiment of the present invention;

FIG. 5 is a flowchart showing a process of forming an organic layer (sixth layer);

FIG. 6A is a graph showing a electric current value with respect to a film-forming time;

FIG. 6B is a graph showing a electric current value with respect to a film-forming time; and

FIG. 7 is a diagram for describing a film-forming process of an organic layer (sixth layer).

### MODES FOR CARRYING OUT THE INVENTION

Hereinafter, embodiments of the present invention will be described in detail with reference to the attached drawings. Like reference numerals in the attached drawings and the below description denote like elements, and thus a detailed description thereof will not be repeated.

(Process of Manufacturing Organic EL Electronic Device)

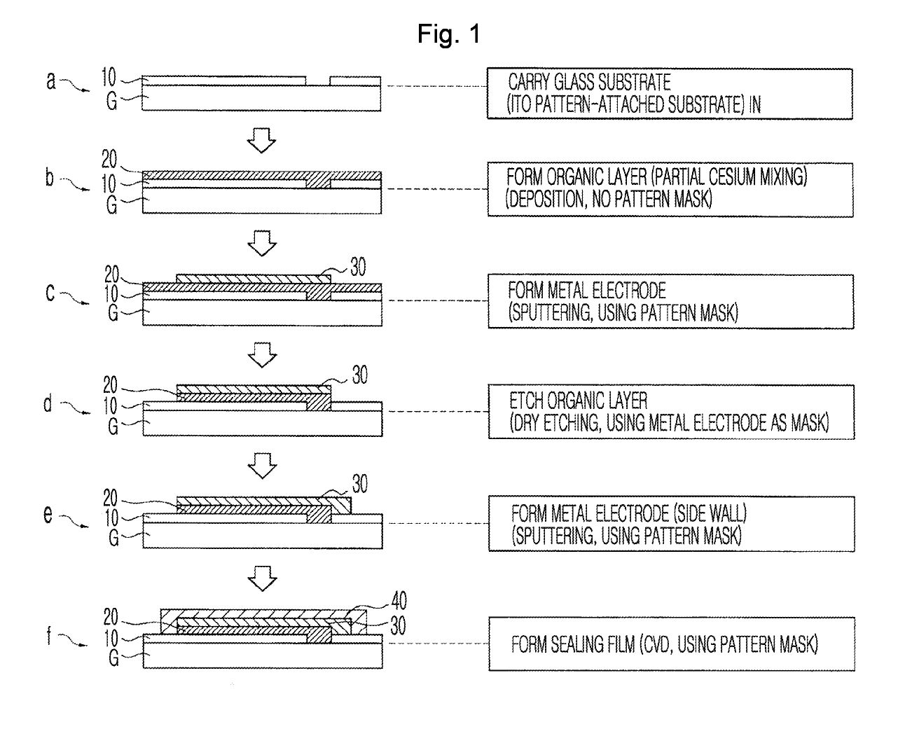

First, a process of manufacturing an organic EL electronic device, according to an embodiment of the present invention will be described with reference to FIG. 1. As shown in “a” of FIG. 1, a glass substrate G (hereinafter, referred to as a substrate G), on which ITO (indium tin oxide) is formed, is carried into a film-forming device, and an organic layer 20 is formed on the ITO (anode) 10, as shown in “b” of FIG. 1. A part of the organic layer 20 is mixed with an alkali metal, and this will be described later.

Then, the substrate G is transferred to a sputtering apparatus, and sputtering atoms (Ag) are sputtered out by colliding ions of an argon gas with the sputtering material formed of silver (Ag). The sputtering atoms (Ag) sputtered are deposited on the organic layer 20 using a pattern mask. Accordingly, a metal electrode (cathode) 30 is formed as shown in “c” of FIG. 1.

Next, the substrate G is transferred to an etching apparatus, and the organic layer 20 is dry etched, using the metal electrode 30 as a mask, by plasma generated by exciting an etching gas supplied into a vessel. Accordingly, as shown in “d” of FIG. 1, only the organic layer 20 disposed below the metal electrode 30 is left on the substrate G.

The substrate G is then transferred back to the sputtering apparatus, and the metal electrode (side wall) 30 is formed, using a pattern mask, by the above-mentioned sputtering, as shown in “e” of FIG. 1.

Then, the substrate G is transferred to a CVD device, such as a RLSA (Radial Line Slot Antenna) plasma CVD device, and an sealing film 40 formed of, for example, hydrogenated silicon nitride (H:SiNx), is formed by using a pattern mask as shown in “f” of FIG. 1. Accordingly, the organic EL element is sealed, and thus is protected from external moisture or the like.

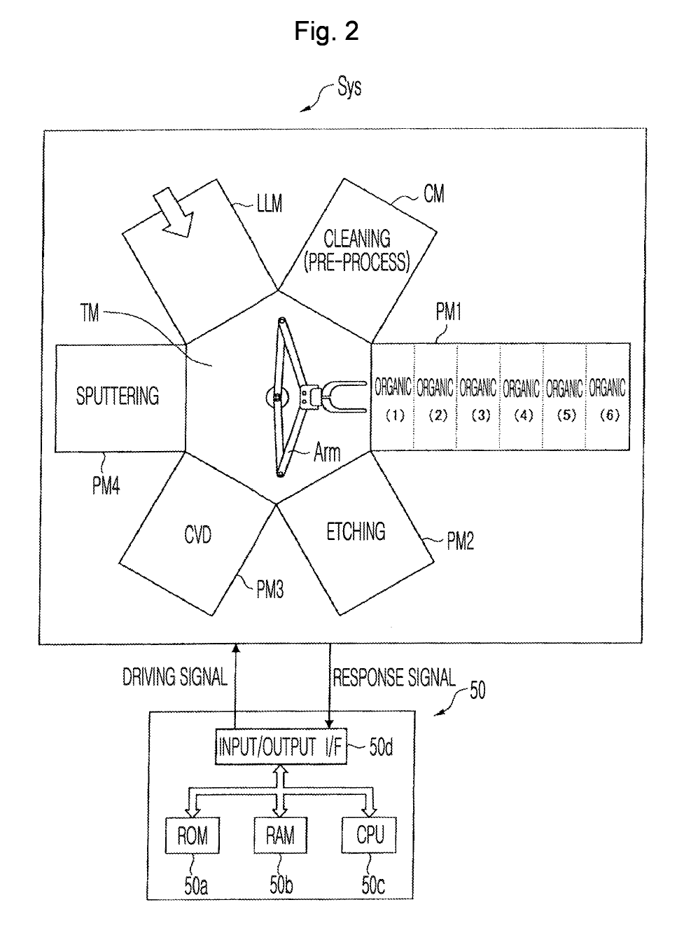

The organic EL electronic device described above may be manufactured in a cluster type substrate-processing system Sys shown in FIG. 2. An entire structure of the substrate-processing system Sys will be described first, and then the transfer and process of the substrate G in the substrate-processing system Sys will be described.

(Entire Structure of Substrate-Processing System, and Transfer and Process of Substrate)

The substrate-processing system Sys according to an embodiment of the present invention is a cluster-type manufacturing apparatus including a plurality of processing vessels. The substrate-processing system Sys includes a load lock module LLM, a transfer module TM, a cleaning module (pre-processing module) CM, and 4 process modules PM1 through PM4 that are processing vessels each performing different processes.

The load lock module LLM is a vacuum transfer module inside of which is maintained in a depressurized state in order to transfer the substrate G received from the atmosphere to the transfer module TM under a depressurized state. The transfer module TM includes a bendable/stretchable and swivelable multi-joint-shaped transfer arm Arm installed roughly at the center. The substrate G is first transferred from the load lock module LLM to the cleaning module CM, to the PM1, and then additionally to the PM2 through PM4, by using the transfer arm Arm. In the cleaning module CM, a contaminant (mainly, an organic material) adhered to the surface of the ITO 10 which serves as an anode layer formed on the substrate G is removed.

In the PM1 through PM4, first, 6 layers of the organic layer 20 are consecutively formed on the surface of the ITO of the substrate by evaporation in the PM1. Specifically, an electron transport layer and an electron injection layer of a sixth layer is formed on the same layer by evaporating an organic material while mixing cesium into a part of the organic material.

Then, the substrate G is transferred to the PM4. In the PM4, the metal electrode 30 is formed on the organic layer 20 of the substrate G by sputtering. Then, the substrate G is transferred to the PM2, and a part of the organic layer 20 is removed by etching, using the metal electrode 30 as a pattern mask.

Next, the substrate G is transferred back to the PM4, and a sidewall of the metal electrode 30 is formed by sputtering in the PM4. Lastly, the substrate G is transferred to the PM3, and the sealing film 40 is formed by CVD in the PM3.

(Controller)

A controller 50 controls the above-mentioned process using the substrate-processing system Sys. The controller 50 includes a ROM 50a, a RAM 50b, a CPU 50c, and an input and output I/F (interface) 50d. The ROM 50a and the RAM 50b store, for example, data or control programs to control a amount of cesium to be mixed while the organic layer (sixth layer) 20 is formed.

The CPU 50c generates a driving signal for controlling the transfer or process in the substrate-processing system Sys, by using the data or control programs stored in the ROM 50a and the RAM 50b. The input and output I/F 50d outputs the driving signal generated by the CPU 50c to the substrate-processing system Sys, and thus receives a response signal outputted from the substrate-processing system Sys and transfers the response signal to the CPU 50c. Also, the controller 50 corresponds to a control portion which controls the proportion of an alkali metal to be mixed into the organic material for forming the sixth layer of an evaporated organic layer.

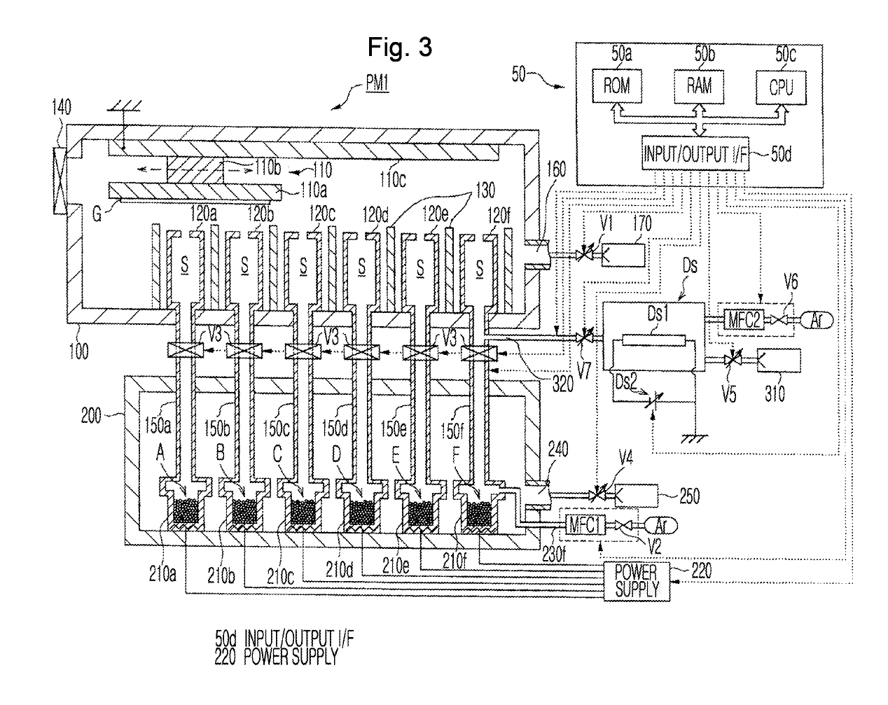

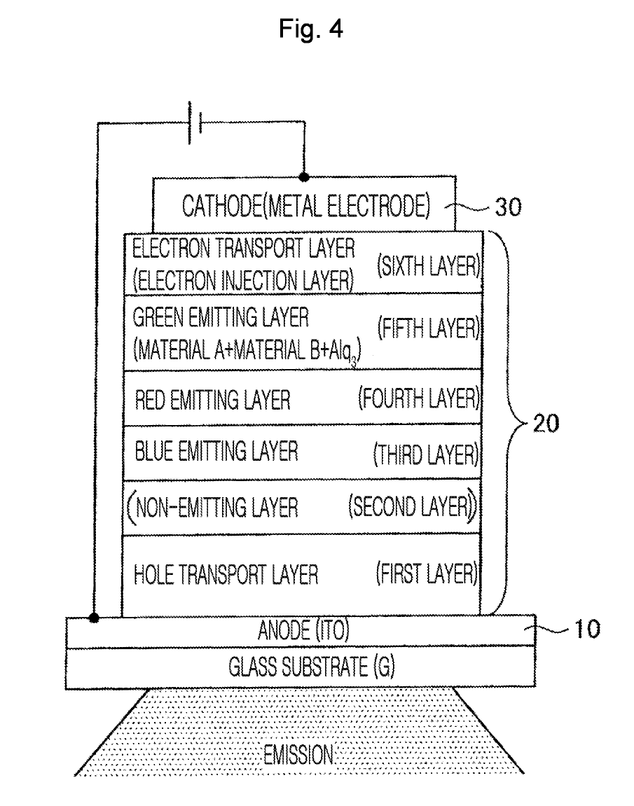

An internal structure of a film-forming device (PM1) included in the substrate-processing system Sys and used to form an organic film, and a stacked structure of the organic film will now be described with reference to FIGS. 3 and 4.

(Film-Forming of an Organic Film: PM1)

As it is schematically shown in a vertical cross-section of FIG. 3, the PM1 includes a processing vessel 100, a evaporation device 200, and a dispenser Ds serving as a second evaporation source. Each component is controlled by the controller 50, and accordingly, six layers of the organic layer 20 are consecutively formed in the processing vessel 100.

<Processing Vessel>

The processing vessel 100 has a rectangular parallelepiped shape, and includes a transferring and loading mechanism 110, six discharge mechanisms 120a through 120f, and seven compartments 130. A gate valve 140 capable of carrying the substrate G in and out by being opened or closed is installed on a sidewall of the processing vessel 100.

The transferring and loading mechanism 110 includes a stage 110a, a holding stage 110b, and a moving mechanism 110c. The stage 110a is supported by the holding stage 110b, and electrostatically-adsorbs the substrate G carried in from the gate valve 140 by a high voltage applied from a high voltage source (not shown). The moving mechanism 110c is installed on the ceiling portion of the processing vessel 100 and is also grounded, and thus moves the substrate G together with the stage 110a and the holding stage 110b in a length direction of the processing vessel 100. Thus, the substrate G is moved parallelly in a space slightly above each discharge mechanism 120. Also, the stage 110a corresponds to a loading table that is movable while a object is placed thereon.

The six discharge mechanisms 120a through 120f have identical shapes and identical structures and are arranged in parallel to each other at regular intervals. The discharge mechanisms 120a through 120f have hollow rectangular interiors (hereinafter, this space will be referred to as a buffering space S), and organic molecules are discharged from openings formed in the upper center of the discharge mechanisms 120a through 120f. The bottoms of the discharge mechanisms 120a through 120f are connected to first gas supply pipes 150a through 150f that penetrate a bottom wall of the processing vessel 100.

The compartment 130 separate each of the discharge mechanisms 120 from one another, thereby preventing the organic molecule discharged from each of the openings of discharge mechanisms 120 from being mixed with the organic molecule discharged from the opening of the next discharge mechanism 120.

An exhaust port 160 is formed in the processing vessel 100. The exhaust port 160 is connected to a vacuum pump 170 through an opening-degree adjustable valve V1. By adjusting an opening degree of the valve V1 based on the driving signal output from the controller 50, the inner pressure of processing vessel 100 may be controlled to a desired vacuum level.

<Evaporation Device>

The evaporation device 200 includes six evaporation sources 210a through 210f having identical shapes and identical structures. The evaporation sources 210a through 210f each contain different organic materials A through F therein. Heaters are embedded in the bottom surface of containers each containing the organic materials A through F, and each heater is connected to a power supply 220 formed outside the evaporation device 200. The evaporation source 210f corresponds to a first evaporation source which evaporates the organic material F by heating the organic material F.

The power supply 220 outputs a desired power based on a driving signal output from the controller 50, thereby heating the evaporation sources 210a through 210f, respectively. As such, the temperature of each evaporation source becomes high, about 200 to 500° C., thereby evaporating each of the organic materials A through F. Here, the term “evaporation” denotes not only a phenomenon in which liquid changes to gas but also a phenomenon in which solid is directly changed to gas by skipping a liquid phase (that is, sublimation).

Gas lines for supplying an argon gas are formed in the evaporation sources 210a through 210f. In FIG. 3, only a gas line 230f for supplying an argon gas to the evaporation source 210f is shown. The argon gas output from an argon gas supply source passes through the gas line 230f and is supplied into the evaporation source 210f. Supply/cutoff and a flow rate of the argon gas are adjusted by controlling a mass flow controller MFC1 and a valve V2 connected to the gas line 230f, based on the driving signal output from the controller 50.

The evaporation sources 210a through 210f are respectively connected to the first gas supply pipes 150a through 150f at the upper portions thereof. The first gas supply pipes 150a through 150f are heated based on the driving signal output from the controller 50, and thus maintain a predetermined high temperature. Accordingly, the organic molecules A through F evaporated in each evaporation source 210 are transported to the each discharge mechanism 120 through a gas passage (first gas supply path) inside each first gas supply pipes 150, and then emitted into the processing vessel 100 from the opening of each discharge mechanism 120, without being attached to each first gas supply pipes 150, by using the argon gas supplied from the gas line 230f as a carrier gas.

Opening-degree adjustable valves V3 (corresponding to the first opening/closing mechanism) are each installed in a downstream side of each first gas supply pipe 150. The opening-degree of the valve V3 is adjusted based on the driving signal output from the controller 50, thereby controlling the supply amount of each organic material passing through each first gas supply pipe 150.

An exhaust port 240 is formed in the evaporation device 200. The exhaust port 240 is connected to a vacuum pump 250 through an opening-degree adjustable valve V4. The inner space of the evaporation device 200 is controlled to a desired vacuum level by adjusting an opening degree of the valve V4 based on the driving signal output from the controller 50.

<Second Evaporation Source: Dispenser>

The dispenser Ds (corresponding to the second evaporation source) for heating and evaporating cesium is provided outside the processing vessel 100. An evaporation container Ds1 is formed inside the dispenser Ds to contain an alkali metal, such as cesium, or the like. The evaporation container Ds1 is connected to a power supply Ds2. A desired voltage is applied to the power supply Ds2 based on the driving signal output from the controller 50, and thus a desired electrical current flows through the evaporation container Ds1. Accordingly, the evaporation container Ds1 is heated and maintained at a desired temperature. Accordingly, an evaporation amount of cesium contained in the evaporation container Ds1 may be adjusted. Also, a metal (corresponding to the second metal) contained in the evaporation container Ds1 may be an alkali metal having a lower work function than the first metal. Examples of the second metal include lithium, sodium, potassium, rubidium, and cesium. The first metal may be a material (including an alloy) mainly including silver or aluminum.

The dispenser Ds is connected to a vacuum pump 310 through an opening-degree adjustable valve V5. The inner pressure of the dispenser Ds is controlled to a desired vacuum level by adjusting an opening degree of the valve V5 based on the driving signal output from the controller 50.

Also, the dispenser Ds is connected to an argon gas supply source through a mass flow controller MFC2 and a valve V6, which adjust a flow rate of a gas. Supply/cutoff and a flow rate of the argon gas are adjusted by controlling the mass flow controller MFC2 and the valve V6 based on the driving signal output from the controller 50. The dispenser Ds and the first gas supply pipe 150f are connected to each other through a second gas supply pipe 320.

Accordingly, the cesium evaporated in the dispenser Ds is transferred into the processing vessel through a path (the second gas supply passage) of the inside of the second gas supply pipe 320 by using a certain amount of argon gas transmitted into the dispenser Ds as a carrier gas. Here, temperatures of a passage (including the second gas supply pipe 320), through which the argon gas and the steam of cesium pass, and dispenser Ds are adjusted to be, for example, 200° C. or higher, based on the driving signal output from the controller 50. Accordingly, when the steam of cesium is transferred by the argon gas, the steam of cesium may be prevented from being adhered to the passage, or the like, and liquefied thereon. Accordingly, the proportion of the second metal to be mixed into the organic layer may be precisely controlled, while increasing an efficiency of use of material.

An opening-degree adjustable valve V7 (corresponding to the second opening/closing mechanism) is installed in the second gas supply pipe 320, and an opening degree of the valve V7 is adjusted based on the driving signal output from the controller 50, thereby controlling the supply amount of cesium passing through the second gas supply pipe 320.

The second gas supply pipe 320 is connected to the first gas supply passage 150f at a more downstream side than the valve V3. Accordingly, the molecules of the organic material F that passed through the first gas supply pipes 150f and the molecules of cesium are mixed with each other while being transported toward the discharge mechanism 120f.

A mixture gas of the organic material F and the cesium, which reached the discharge mechanism 120f, is discharged into the processing vessel through a narrowed discharge opening, and thus an amount of discharged gas molecules is limited. Accordingly, gas molecules that exceed a predetermined amount, from among the gas molecules entered into the buffering space S, are unable to directly pass through a discharge opening, and temporarily stay in the buffering space S. As such, the gas molecules are temporarily stayed in the buffering space S so that the pressure of the buffering space S is higher than the external pressure of the discharge mechanism 120f (i.e., the pressure of a processing chamber U), and thus the gas molecules are uniformly mixed while staying in the buffering space S. The uniformly mixed gas molecules are discharged from the discharge opening toward the substrate G in a uniform state.

According to the above-described film-forming device, among the organic molecules discharged from each discharge mechanism 120, the organic molecule discharged from the discharge mechanism 120a is first attached to the ITO (anode) on the substrate G that moves above the discharge mechanism 120a at a predetermined speed, and thus a hole transport layer of a first layer is formed on the substrate G as shown in FIG. 4. Then, as the substrate G moves in the order from the discharge mechanism 120b to the discharge mechanism 120e, the organic molecules A through E discharged from the discharge mechanisms 120b through 120e are each deposited on the substrate G, and thus the organic layers (second through fifth layers) are sequentially formed. Lastly, the organic molecules F that are mixed with cesium are deposited on the substrate G from the discharge mechanism 120f, and thus an electron transport layer (electron injection layer) constituting a sixth layer of the organic layer is formed.

As such, the organic layer 20 is formed on the ITO (anode) 10 of the substrate G. After the film-formation, the substrate G is immediately transferred to the PM4, and the metal electrode 30 is formed on the organic layer 20 by sputtering.

(Film-Forming Processing of Organic Layer (Sixth Layer))

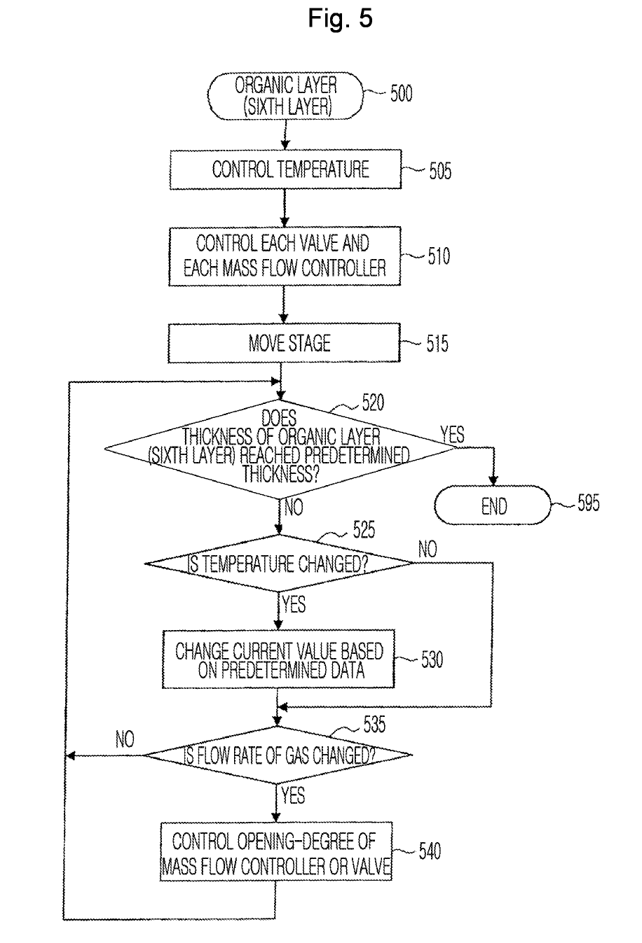

Now, a process of film-forming the organic layer (sixth layer) while mixing cesium (Cs) into the organic layer in the film-forming device having the above-described structure will be described with reference to FIG. 5, which shows the process procedure performed by the controller 50.

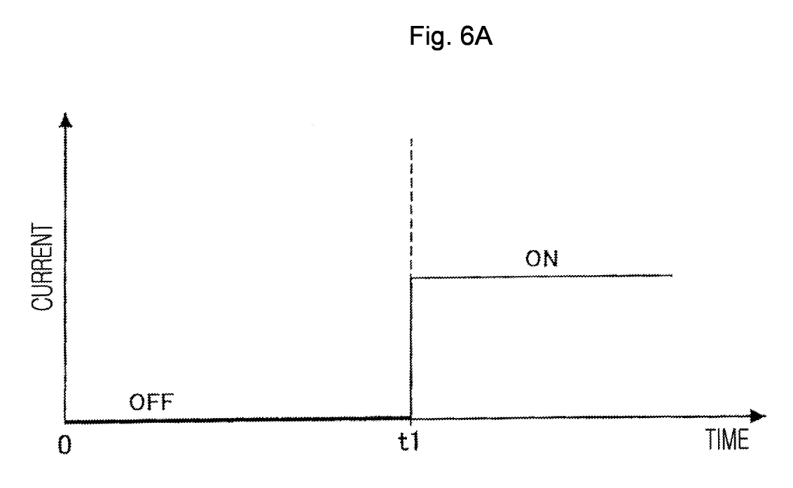

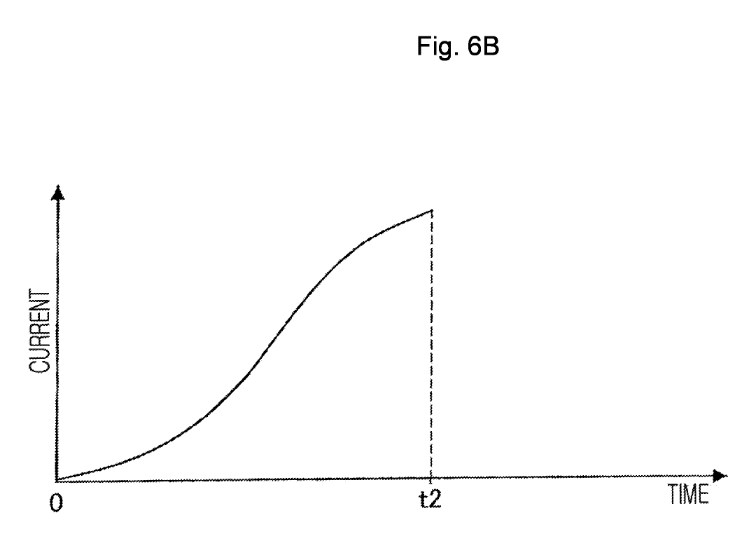

The process of film-forming the organic layer (sixth layer) starts in step 500, and the controller 50 controls a temperature of each element in step 505. As one example of controlling the temperature, the controller 50 controls an electric current value (a voltage value of the power supply Ds2) flowing through the evaporation container Ds1 formed in the dispenser Ds. For example, as shown in FIG. 6A, when the ROM 50a stores data for controlling the electric current value with respect to a film-forming time, the controller 50 may set the electric current value to be 0 (an OFF value) in step 505, based on the data stored in the ROM 50a. Here, the cesium is not evaporated until a time t1 is passed.

As another example of controlling the temperature, the controller 50 may control the heater of the evaporation source 210f or a heater (not shown) embedded in the first gas supply pipe 150f, the second gas supply pipe 320, or the like to a predetermined temperature, such as 200° C. or higher.

Then, the controller 50 controls the flow rate of the organic material F or of the argon gas passing through the first gas supply pipe 150f, or controls the flow rate of the cesium molecules or of the argon gas passing through the second supply pipe 320 by controlling each valve and each mass flow controller, in step 510. As described above, the valve V7 is fully closed so as to control the cesium not to be mixed into the organic layer (sixth layer) until the process time t1. Also, the valve V3 is adjusted so that a predetermined amount of the organic molecular F is supplied from the discharge opening of the discharge mechanism 120f.

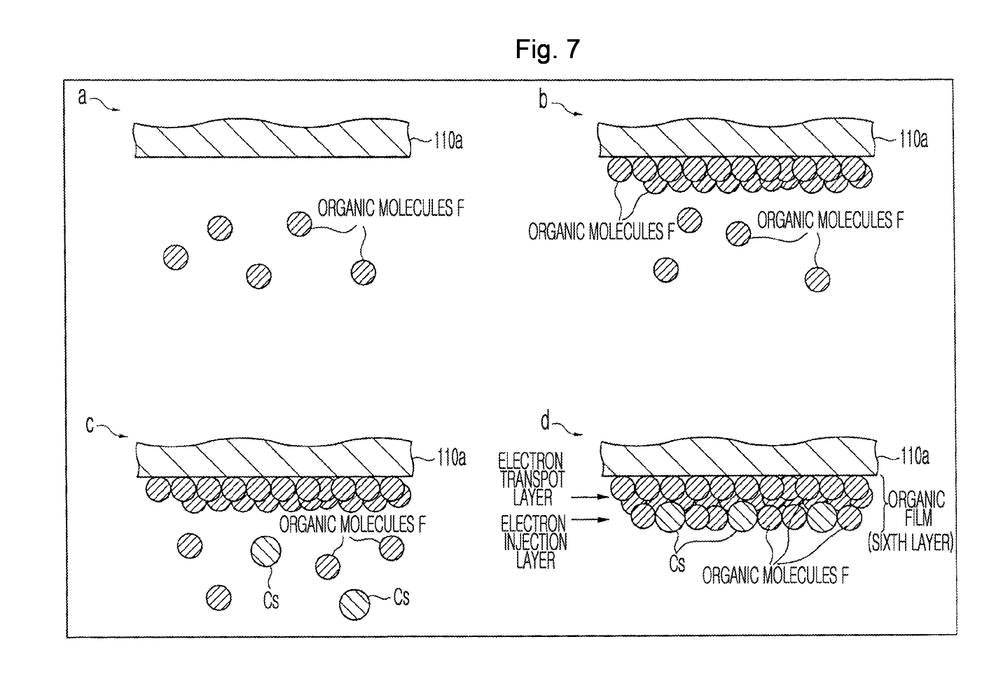

Next, in step 515, the controller 50 moves the stage 110a to above the discharge mechanism 120f. Accordingly, as shown in “a” of FIG. 7, the organic molecules F are emitted from the discharge opening of the discharge mechanism 120f toward the stage 110a.

Here, a proportion of the cesium (Cs) mixed into the organic layer (sixth layer) is very important. This is well known from a research result that, in a conventional organic EL electronic device manufactured by stacking an electron transport layer, an electron injection layer, and a metal electrode (cathode) on a light emission layer, it is better for a thickness of an alkali metal forming the electron injection layer to be relatively smaller than a thickness of the metal electrode (cathode) or the electron transport layer. For example, it has been reported that when lithium is used as the electron injection layer, the thickness of the lithium may be from about 0.5 to about 2.0 nm, and if the thickness is higher, electron injection efficiency is deteriorated.

Thus, in the present embodiment, considering the importance of the mixed proportion of cesium (Cs), the temperature of the dispenser Ds is controlled as a method of controlling the proportion of cesium (Cs) mixed into the organic layer 20. In other words, the controller 50, after determining that the sixth layer of the organic layer is not formed up to a predetermined thickness in step 520, controls whether to change the temperature of the dispenser Ds in step 525. As shown in FIG. 6A, the electric current flowing through the dispenser Ds is turned off until the predetermined time t1 is passed. In other words, the voltage is not applied to the power supply Ds2. Accordingly, before the predetermined time t1 is passed, the controller 50 skips step 530 and determines whether to change the gas flow rate in step 535. If it is required to change a film-forming rate by changing a gas flow rate, the controller 50 performs step 540, thereby adjusting the opening degree of the valve V3 to control the film-forming rate. In this process, as shown in “b” of FIG. 7, a thin film where only the organic molecules F are stacked is formed.

When the predetermined time t1 is passed while repeating steps 520 through 540, the controller 50 changes the temperature. In other words, in step 530 after steps 520 and 525, the controller 50 controls the electric current flowing through the dispenser Ds to be on (a predetermined voltage is applied to the power supply Ds2), as shown in FIG. 6A.

Next, the controller 50 performs step 535 to determine whether to change a gas flow rate. After the predetermined time t1, it is required to form the electron injection layer by mixing cesium (Cs) into the organic layer. Thus, the controller 50 determines to change the gas flow rate in step 535 and adjusts the opening degree of the valve V7 in step 540, thereby controlling the amount of cesium (Cs) passing through a path of the second gas supply pipe 320. At the same time, the controller 50 adjusts the mass flow controller MFC2 and the valve V6 in the same step 540, thereby changing the flow rate of the argon gas, and accordingly, controls the amount of cesium (Cs) passing through a path of the second gas supply pipe 320 per unit time. Thus, as shown in “c” of FIG. 7, each gas is emitted from the discharge opening of the discharge mechanism 120f toward the stage 110a in a state in which the cesium (Cs) is mixed into the organic molecules F.

At this time, when the film-forming is performed and the organic layer (sixth layer) is formed up to a predetermined thickness, the controller 50 performs step 595 from step 520, thereby completing the process. At this time, as shown in “d” of FIG. 7, among the organic layer (sixth layer), only a thin film of the organic molecules F that are not mixed with the cesium (Cs) is formed as the electron transport layer, and then, a very thin film of the organic molecules F that are mixed with the cesium (Cs) is formed as the electron injection layer.

As described above, in the method of forming the organic layer (sixth layer) according to the present embodiment, the alkali metal is mixed into the organic layer, thereby substantially forming the electron injection layer and the organic layer simultaneously. Accordingly, the active alkali metal is strongly prevented from reacting with moisture, nitrogen, oxygen, or the like, thereby manufacturing an organic EL electronic device having high electron injection efficiency.

Also, in the method of forming the organic layer according to the present embodiment, a proportion of the alkali metal mixed into the sixth layer of the organic layer 20 may be controlled by using various control method. In detail, as described above, for example, the temperature of the dispenser Ds is controlled to control an evaporation rate of the alkali metal contained in the dispenser Ds, thereby controlling the proportion of the alkali metal mixed into the organic layer 20. The temperature of the evaporation source 210f may be controlled to control the evaporation rate of the organic material F, thereby controlling the proportion of the alkali metal mixed into the organic layer 20.

Alternatively, a flow rate of an inert gas, such as the argon gas, supplied to the evaporation source 210f or the dispenser Ds is controlled to control the amount of the organic material or the amount of the alkali metal passing through each gas supply path per unit hour, thereby controlling the proportion of the alkali metal mixed into the organic layer 20. By doing so, the amount of the alkali metal mixed during formation of the sixth layer of the organic layer 20 may be accurately controlled by approximate control of the temperature control and precise control of the flow rate of the inert gas serving as a carrier gas.

The proportion of the alkali metal to be mixed into the organic layer 20 may be controlled by controlling a proportion of the total flow rate of the gas supplied from the first gas supply pipe 150f into the processing vessel to the total flow rate of the gas supplied from the second gas supply pipe 320 into the processing vessel.

In the above embodiment, the organic layer (electron transport layer) that is not mixed with the alkali metal is formed, and consecutively the organic layer (electron injection layer) that is mixed with the alkali metal is film-formed on the electron transport layer. Alternatively, as shown in FIG. 6B, the electric current amount flowing through the dispenser Ds may be gradually increased so as to increase the evaporation amount of the alkali metal. Accordingly, the amount of the alkali metal mixed into the organic layer 20 may be gradually increased. Consequently, the alkali metal is mixed into the organic layer in such a way that the number of atoms of the alkali metal increases closer to the cathode, and decreases away from the cathode.

As described above, according to the embodiments, it is possible to simultaneously film-form the alkali metal having a low work function and the organic layer, and thus a highly efficient organic EL electronic device can be stably manufactured without oxidizing the alkali metal that is easily activated.

In the above-mentioned embodiments, operations of each component are related to each other, and considering the relation between the components, the operations may be replaced by a series of operations. Due to this replacement, the embodiments of a film-forming device for manufacturing the organic EL electronic device may be embodiments of a film-forming method for manufacturing the device and a method of controlling a film-forming device for manufacturing the device.

While the present invention has been particularly shown and described with reference to exemplary embodiments thereof, it will be understood by those of ordinary skill in the art that various changes in form and details may be made therein without departing from the spirit and scope of the present invention as defined by the following claims.

For example, in the present embodiments, the alkali metal is mixed into the sixth layer of the organic layer 20, but while mixing the alkali metal into the organic layer 20, the alkali metal may also be mixed into the metal electrode 30 formed after the organic layer 20.

Also, in the present embodiments, the processing vessel 100 and the evaporation device 200 of the film-forming device are separately formed, but the evaporation source of each organic material may be installed in one processing vessel.

Moreover in the present embodiments, the second gas supply pipe 320 is connected to the first gas supply pipe 150f, but the first gas supply pipe 150f and the second gas supply pipe 320 may be individually connected to the discharge mechanism 120f.

In addition, the object may be a substrate having a size equal to or greater than 730 mm×920 mm, or a silicon wafer having a size equal to or greater than 200 mm or 300 mm.

1. A method of controlling a film-forming device which forms an organic layer on an object,
wherein the film-forming device comprises:
a processing vessel;
a first evaporation source for heating and evaporating an organic material;
a first gas supply passage for communicating with the first evaporation source and transporting the organic material evaporated in the first evaporation source by using an inert gas;
a second evaporation source provided outside the processing vessel and heating and evaporating a second metal having a lower work function than that of a first metal forming a cathode;
a second gas supply passage communicating with the second evaporation source and transporting the second metal evaporated in the second evaporation source by using an inert gas; and
a discharge mechanism communicating with the first gas supply passage and the second gas supply passage, mixing the evaporated second metal into the evaporated organic material and discharging the mixture toward the object in the processing vessel,
wherein the proportion of the evaporated second metal mixed into the evaporated organic material is controlled.

2. The method of claim 1, wherein the proportion of the evaporated second metal mixed into the evaporated organic material is controlled by controlling a temperature of the first evaporation source.

3. The method of claim 1, wherein the proportion of the evaporated second metal mixed into the evaporated organic material is controlled by controlling a temperature of the second evaporation source.

4. The method of claim 1, wherein the proportion of the evaporated second metal mixed into the evaporated organic material is controlled by increasing or decreasing a flow rate of at least any one of inert gases supplied to the first gas supply passage and the second gas supply passage.

5. The method of claim 1, wherein the proportion of the evaporated second metal mixed into the evaporated organic material is controlled by controlling a first opening/closing mechanism provided in the first gas supply passage.

6. The method of claim 1, wherein the proportion of the evaporated second metal mixed into the evaporated organic material is controlled by controlling a second opening/closing mechanism provided in the second gas supply passage.

7. The method of claim 5, wherein the first mechanism and the second opening/closing mechanism are provided in the atmosphere.

8. The method of claim 1, wherein a thin film is formed on the object up to a desired thickness by using the evaporated organic material without mixing the evaporated second metal, and then a predetermined amount of the evaporated second metal is mixed into the evaporated organic material.

9. The method of claim 8, wherein the organic layer that is not mixed with the second metal and the organic layer that is mixed with the second metal are formed between a light emission layer and the cathode.

10. The method of claim 1, wherein an amount of the second metal mixed into the evaporated organic material is controlled to relatively increase.

11. The method of claim 1, wherein pipes for forming the first gas supply passage and the second gas supply passage are controlled to be 200° C. or higher.

12. The method of claim 1, wherein the second metal is an alkali metal and the first metal is a material consisting of mainly silver or aluminum.

13. The method of claim 10, wherein the film-forming device comprises:
a loading stage which is movable with the object placed thereon;
a plurality of evaporation sources including the first evaporation source;
a plurality of gas supply passage including the first gas supply passage communicating with each of the plurality of evaporation sources; and
a plurality of discharge mechanisms,
wherein different organic materials each evaporated from each evaporation source are passed through each gas supply passage communicating with each evaporation source to be discharged from each discharge mechanism, so as to consecutively film-form the different organic materials on the object placed on the loading table moving above each discharge mechanism, and the organic layer that is mixed with the evaporated second metal is film-formed at the end of the consecutive film-formation.

14. The method of claim 1, wherein the discharge mechanism has a buffering space therein, and discharges the evaporated organic material and the evaporated second metal after passing the evaporated organic material and the evaporated second metal through the buffering space, so that a pressure of the buffering space formed inside the discharge mechanism is higher than a pressure inside the processing vessel.

15. A film-forming method for forming an organic layer on an object, the film-forming method comprising:
heating and evaporating an organic material in a first evaporation source;
transporting the evaporated organic material by using an inert gas;
heating and evaporating a second metal having a lower work function than that of a first metal forming a cathode, in a second evaporation source formed outside a processing vessel;
transporting the evaporated second metal by using an inert gas; and
mixing the evaporated second metal into the evaporated organic material while controlling a proportion of the second metal to be mixed into the evaporated organic material, and discharging the evaporated organic material toward the object in the processing vessel.

16. A film-forming device for forming an organic layer on a object, the film-forming device comprising:
a processing vessel;
a first evaporation source for heating and evaporating an organic material;
a first gas supply passage for communicating with the first evaporation source and transporting the organic material evaporated in the first evaporation source by using an inert gas;
a second evaporation source provided outside the processing vessel and heating and evaporating a second metal having a lower work function than that of a first metal forming a cathode;
a second gas supply passage communicating with the second evaporation source and transporting the second metal evaporated in the second evaporation source by using an inert gas; and
a discharge mechanism communicating with the first gas supply passage and the second gas supply passage and mixing the evaporated second metal into the evaporated organic material and discharging the mixture toward the object in the processing vessel,
a controller for controlling a proportion of the second metal to be mixed into the evaporated organic material.

17. An organic EL electronic device manufactured by controlling a film-forming device according to the method of claim 1.

18. A recording medium having recorded thereon a control program having processing procedure to be executed on a computer so as to control a film-forming device by using the method of claim 1.
